(19) United States
(12) Patent Application Publication
(10) Pub. No.: US 2026/0114017 A1
(43) Pub. Date: Apr. 23, 2026

(54) SEMICONDUCTOR DEVICE AND METHOD FOR FABRICATING THE SAME

(71) Applicant: Silicon-Magic Semiconductor Technology (Hangzhou) Co., Ltd., Hangzhou (CN)

(72) Inventors: He SUN, Hangzhou (CN); Jiakun WANG, Hangzhou (CN)

(73) Assignee: Silicon-Magic Semiconductor Technology (Hangzhou) Co., Ltd., Hangzhou (CN)

(21) Appl. No.: 19/322,717

(22) Filed: Sep. 9, 2025

(30) Foreign Application Priority Data
Oct. 21, 2024 (CN) 2024114714176

(51) Int. Cl. H10D 64/27; H10D 30/01; H10D 30/65; H10D 64/01; H10D 84/82

(52) U.S. Cl. CPC H10D 64/518; H10D 30/0281; H10D 30/65; H10D 64/027; H10D 64/513; H10D 64/516; H10D 84/82

(57) ABSTRACT

A semiconductor device including a semiconductor layer, a plurality of first device structures and a plurality of second device structures. The semiconductor layer includes a first region and a second region. The plurality of first device structures are formed in the first region. One of the plurality of first device structures is one of the bipolar device, the CMOS (complementary metal-oxide-semiconductor transistor) device and the DMOS (double diffusion metal-oxide-semiconductor transistor) device. The plurality of second device structures are formed in the second region. At least one of the plurality of second device structures includes a trench power device with a T-shaped gate electrode.

### CROSS-REFERENCE TO RELATED APPLICATION

This application claims the benefit of Chinese patent application No. 202411471417.6, filed on Oct. 21, 2024, which is incorporated herein by reference in its entirety.

### TECHNICAL FIELD

The present disclosure relates to semiconductor technology and in particular to a semiconductor device and a method for fabricating the same.

### BACKGROUND

BCD (Bipolar CMOS DMOS) process technology refers to a process technology that integrates bipolar devices, CMOS (complementary metal-oxide-semiconductor transistor) devices, and DMOS (double-diffusion metal-oxide-semiconductor transistor) devices on the same chip. Devices manufactured using BCD process technology combine the advantages of bipolar devices (high transconductance, strong load driving capability), CMOS devices (high integration density, low power consumption), and DMOS devices (high voltage, high current driving capability). However, the devices manufactured using BCD process technology exhibit relatively poor performance in terms of low specific on-resistance.

### SUMMARY

The present disclosure provides a semiconductor device and a method for fabricating the same, enabling the fabrication of a semiconductor device that combines low specific on-resistance with the various advantages of devices manufactured using BCD process technology, through a relatively simple process flow and lower cost.

The embodiments of the present invention are directed to a semiconductor device including a semiconductor layer, a plurality of first device structures and a plurality of second device structures. The semiconductor layer includes a first region and a second region. The plurality of first device structures is formed in the first region. One of the plurality of first device structures is one of the bipolar device, the CMOS (complementary metal-oxide-semiconductor transistor) device and the DMOS (double diffusion metal-oxide-semiconductor transistor) device. The plurality of second device structures are formed in the second region. At least one of the plurality of second device structures includes a trench power device with a T-shaped gate electrode.

The embodiments of the present invention are directed to a method of fabricating a semiconductor device including providing a semiconductor layer, wherein the semiconductor layer comprises a first region and a second region; forming a plurality of first device structures in the first region of the semiconductor layer by BCD process technology; and forming a plurality of second device structures in the second region of the semiconductor layer, wherein at least one of the plurality of second device structures includes a trench power device with a T-shaped gate electrode.

Those skilled in the art will recognize additional features and advantages upon reading the following detailed description, and upon viewing the accompanying drawings.

### BRIEF DESCRIPTION OF FIGURES

The present disclosure can be further understood with reference to following detailed description and appended drawings, wherein like elements are provided with like reference numerals. These drawings are only for illustration purpose, thus may only show part of the devices and are not necessarily drawn to scale. It is obvious that the drawings described below are some implementations of the present disclosure, and those skilled in the art would also obtain other drawings on the basis of these drawings, without involving any inventive skill.

FIG. 1 schematically shows a prior art cross-sectional view of a semiconductor device 100.

FIG. 2 schematically shows a cross-sectional view of a semiconductor device 200 in accordance with an embodiment of the present disclosure.

FIG. 3 schematically shows a cross-sectional view of a semiconductor device 300 in accordance with an embodiment of the present disclosure.

FIG. 4 shows a flowchart of a method 400 for fabricating a semiconductor device in accordance with an embodiment of the present disclosure.

FIGS. 5a to 5f schematically show the cross sectional views of the semiconductor device during conducting the steps of the method 400, in accordance with an embodiment of the present disclosure.

The use of the same reference label in different drawings indicates the same or like components.

### DETAILED DESCRIPTION

Various embodiments of the present disclosure will now be described. In the following description, some specific details, such as example circuits and example values for these circuit components, are included to provide a thorough understanding of embodiments. One skilled in the relevant art will recognize, however, that the present disclosure can be practiced without one or more specific details, or with other methods, components, materials, etc. In other instances, body-known structures, materials, processes or operations are not shown or described in detail to avoid obscuring aspects of the present disclosure.

Throughout the specification and claims, the terms “left”, “right”, “in”, “out”, “front”, “back”, “up”, “down”, “top”, “atop”, “bottom”, “on”, “over”, “under”, “above”, “below”, “vertical” and the like, if any, are used for descriptive purposes and not necessarily for describing permanent relative positions. It is to be understood that the terms so used are interchangeable under appropriate circumstances such that embodiments of the technology described herein are, for example, capable of operation in other orientations than those illustrated or otherwise described herein. The phrases “in one embodiment”, “in some embodiments”, “in one implementation”, and “in some implementations” as used includes both combinations and sub-combinations of various features described herein as body as variations and modifications thereof. These phrases used herein does not necessarily refer to the same embodiment, although it may. Those skilled in the art should understand that the meanings of the terms identified above do not necessarily limit the terms, but merely provide illustrative examples for the terms. It is noted that when an element is “connected to” or “coupled to” the other element, it means that the element is directly connected to or coupled to the other element, or indirectly connected to or coupled to the other element via another element. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

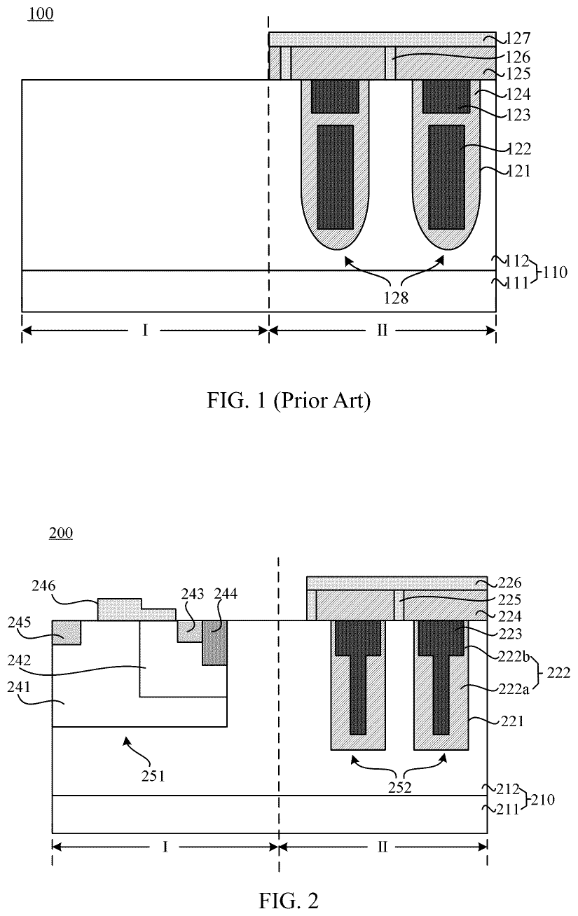

FIG. 1 shows a prior art schematic cross-sectional view of a semiconductor device 100. As shown in FIG. 1, the semiconductor device 100 includes a semiconductor layer 110 divided into a first region I and a second region II in a lateral direction. The semiconductor layer 110 includes a substrate 111 and an epitaxial layer 112 formed on the substrate 111 in a vertical direction. The semiconductor device 100 includes BCD devices (not shown in FIG. 1) formed in the epitaxial layer 112 of the first region I, and SGT (Shielded Gate Trench) devices 128 formed in the epitaxial layer 112 of the second region II. BCD devices includes bipolar devices, CMOS devices, and DMOS devices. The BCD devices are different from the SGT devices 128, mainly in that their respective fabrication processes do not require trench formation.

In FIG. 1, each SGT device 128 includes a deep trench 121 located in the second region II, a shield gate 122, a control gate 123 and a dielectric layer 124 formed in the deep trench 121. The control gate 123 is arranged above and distanced from the shield gate 122. The shield gate 122 and the control gate 123 are insulated from the sidewalls and the bottom surface of the deep trench 121 by the dielectric layer 124. Furthermore, an insulating layer 125, conductive pillars 126, and a conductive layer 127 are positioned on a surface of the epitaxial layer 112 in the second region II. The insulating layer 125 is formed on the surface of the epitaxial layer 112 in the second region II. The conductive layer 127 overlies the insulating layer 125. The conductive pillars extend vertically through the insulating layer 125 to connect the conductive layer 127 to selective regions of the surface of the epitaxial layer 112 between neighboring deep trenches 121.

In mid-to-low voltage power device applications, the SGT devices have the advantage of low specific on-resistance. The semiconductor device 100 shown in FIG. 1 combines low specific on-resistance with the various advantages of BCD devices, and could reduce device packaging costs. However, in conventional processes, integrating SGT devices with BCD devices manufactured using BCD process technology suffers from technical problems such as a relatively complex flow, numerous mask layers, high cost, and high demands on process capability.

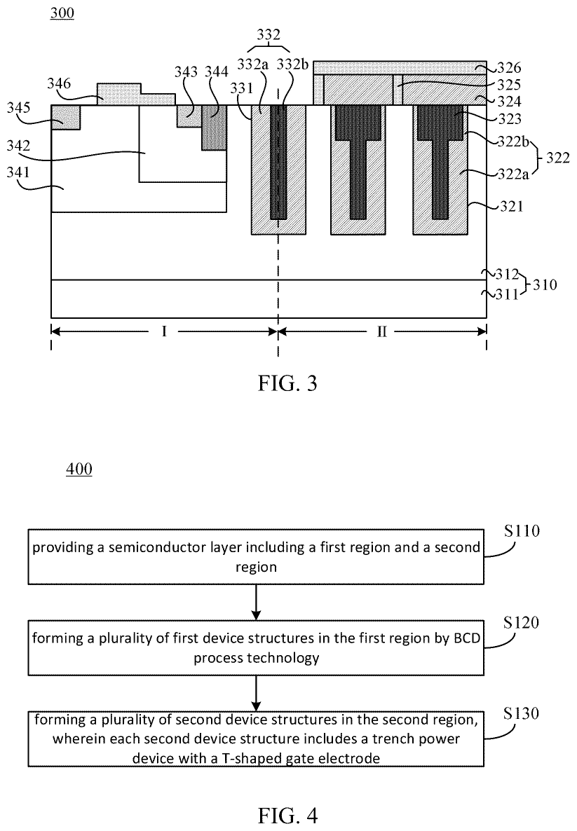

The embodiments of the present disclosure provide semiconductor devices with a novel structure. FIG. 2 schematically shows a cross-sectional view of a semiconductor device 200 in accordance with an embodiment of the present disclosure.

As shown in FIG. 2, the semiconductor device 200 includes a semiconductor layer 210 having a substrate 211 and an epitaxial layer 212 overlying the substrate 211, first device structures 251 and second device structures 252. Along a lateral extent, the semiconductor layer 210 is partitioned into a first region I and an adjacent second region II. In the first region I, the first device structure 251 is formed at a surface of the epitaxial layer 212 and extends perpendicularly inward. In the second region II, the second device structures 252 are formed at the surface of the epitaxial layer 212 and extend perpendicularly inward. The first device structure 251 includes a device structure manufactured using BCD process technology. The second device structure 252 in FIG. 2 is different from the SGT device shown in FIG. 1. Specifically, the second device structure 252 in FIG. 2 has a T-shaped gate electrode 223.

The substrate 211 may be a silicon substrate, strained silicon substrate, germanium substrate, silicon germanium substrate, silicon carbide (SiC) substrate, III-V compound substrate, etc., and is not limited to the examples listed above.

In the embodiment of the present disclosure, compared with the SGT device 128 in FIG. 1, the fabrication process of the second device structure 252 with a T-shaped gate is more consistency with BCD process, and requires fewer mask layers. The semiconductor device 200 could be fabricated through a relatively simple process and at a lower cost. Furthermore, the second device structure 252 with the T-shaped gate has a lower specific on-resistance than the SGT device. As such, the semiconductor device 200 combines low specific on-resistance with the various advantages of devices 251 manufactured using BCD process technology.

The first device structure 251 in FIG. 2 is manufactured by BCD process technology and is exemplarily represented by a DMOS device. The DMOS device 251 includes a drift region 241, a body region 242, a drain region 245, a source region 243, a gate electrode 246 and a body contact region 244. The gate electrode 246 overlies the drift region 242. On one side of the gate electrode 246, the body region 242 is formed in the drift region 242 with its partial extent laterally underlying the gate electrode 246. The body region 242 extends vertically from the surface into the drift region 242. The source region 243 and the body contact region 244 are formed in the body region 242 and are adjacent to each other. On an opposite side of the gate electrode 246, the drain region 245 is formed in the drift region 242, and is laterally distanced from the body region 242. The drift region 241, the source region 243, and the drain region 245 have the same doping type. The body region 242 and the body contact region 244 have the same doping type, which is different from that of the drift region 241. These doped regions can be formed by ion implantation processes. It should be understood that the devices manufactured using BCD process technology includes the bipolar devices, the CMOS devices, and the DMOS devices. In the example shown in FIG. 2, the bipolar devices, the CMOS devices could also be formed in the epitaxial layer 212 together with the DMOS device 251 along a direction perpendicular to the cross sectional view in FIG. 2, or may be formed in the epitaxial layer 212 together with the DMOS device along the lateral direction parallel to the cross sectional view in FIG. 2. For illustrative clarity, the DMOS device 251 is shown in FIG. 2 while the bipolar devices and the CMOS devices are omitted.

In the embodiment of FIG. 2, the second device structures 252 include trenches 221 with a T-shaped gate electrode 223 in each one of the trenches 221. The trench 221 is formed in the epitaxial layer 212 in the second region II. The T-shaped gate electrode 223 is positioned in the trench 221 with a gate dielectric layer 222 in between. The gate dielectric layer 222 includes a second dielectric layer 222a and a third dielectric layer 222b. The second dielectric layer 222a covers the sidewalls and bottom surface of a lower section of the second trench 221. The third dielectric layer 222b covers the sidewalls of an upper section of the second trench 221. The third dielectric layer 222b is above and is in contact with the second dielectric layer 222a. The thickness of the third dielectric layer 222b is less than that of the second dielectric layer 222a. Therefore, filling the second trench 221 after the second dielectric layer 222a and the third dielectric layer 222b are formed enables the formation of the T-shaped gate electrode 223 as shown in FIG. 2.

Further, the second device structure may also include, as shown in FIG. 2, an insulating layer 224, conductive pillars 225 and a conductive layer 226. The insulating layer 224 overlies the surface of the epitaxial layer 212 in the second region II. The conductive pillars 225 extend vertically through the insulating layer 224 to connect the conductive layer 226 to selective regions of the surface of the epitaxial layer 212 between neighboring trenches 221, i.e., the neighboring second device structures. The conductive pillars 225 and the conductive layer 226 may be made of metal, or other conductive material.

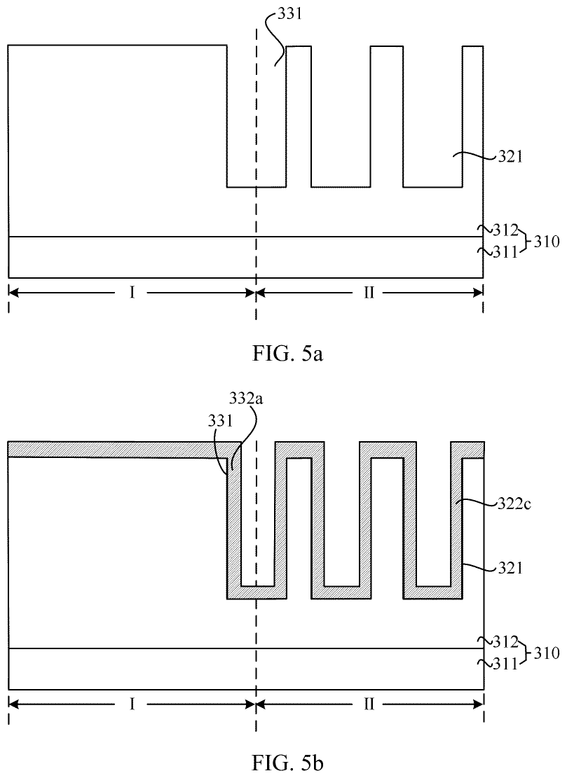

FIG. 3 schematically shows a cross-sectional view of a semiconductor device 300 in accordance with an embodiment of the present disclosure. Compared with the semiconductor layer 200 shown in FIG. 2, the semiconductor device 300 further includes an isolation structure 332 positioned in between the first region I and the second region II. Specifically, a half of the isolation structure 332 is formed in the first region I and the other half is formed in the second region II. The isolation structure 332 includes a trench 331, an insulating structure having an electrode 332b and a dielectric layer 332a insulating the electrode 332b from the trench 331. As provided with the embodiment in FIG. 2, multiple devices manufactured using BCD process technology (also referred as BCD devices) in the first region I may be arranged along the direction perpendicular to the cross sectional view shown in FIGS. 2 and 3. The isolation structure 332 could also be formed in the first region I between the neighboring BCD devices, which is not shown in the sectional view in FIG. 3. Conventional BCD process technology adopts deep wells for isolation between neighboring devices. The deep wells may be formed by implanting N-type or P-type ions into the substrate followed by a drive-in process. The drive-in process causes lateral diffusion of the implanted ions, resulting in an enlarged width of the deep wells in the lateral direction. The isolation structure 332 provided by the semiconductor device 300 of the present disclosure has a highly controlled width in the lateral direction, thereby facilitating increased integration density and miniaturization of the semiconductor device 300.

As shown in FIG. 3, the isolation structure 332 includes a first dielectric layer 332a covering the sidewalls and the bottom surface of the first trench 331. The second dielectric layer 322a covers the bottom surface and the sidewalls of a lower section of the second trench 321. The third dielectric layer 322b covers the sidewalls of an upper section of the second trench 321. The second dielectric layer 322a and the third dielectric layer 322b are integrated into a gate dielectric layer 322. The depth of the first trench 331 and the depth of the second trench 321 are the same. The first dielectric layer 332a and the second dielectric layer 322a are made of the same material and have the same thickness. Therefore, an etching process may be adopted to simultaneously form the first trench 331 and the second trench 321. Deposition or thermal growth may be adopted to simultaneously form the first dielectric layer 332a and a dielectric layer in the second trench 321. The dielectric layer is subsequently patterned to be the second dielectric layer 322a by removing an upper section of the dielectric layer in the second trench 321, facilitating simplification of the fabrication process for the semiconductor device 300.

In the embodiment of FIG. 3, the isolation structure 332 includes the electrode 332b. The electrode 332b is positioned in the first trench 331 and is insulated from the first trench 331 by the first dielectric layer 332a. In the second region II, the T-shaped gate electrode 323 is formed in the second trench 321. The T-shaped gate electrode 323 and the electrode 332b are made of the same material. As such, after forming the first dielectric layer 332a and the gate dielectric layer 322, the first trench 331 and the second trench 321 may be filled simultaneously to form the T-shaped gate electrode 332b and the electrode 323 respectively, facilitating simplification of the fabrication process for the semiconductor device 300.

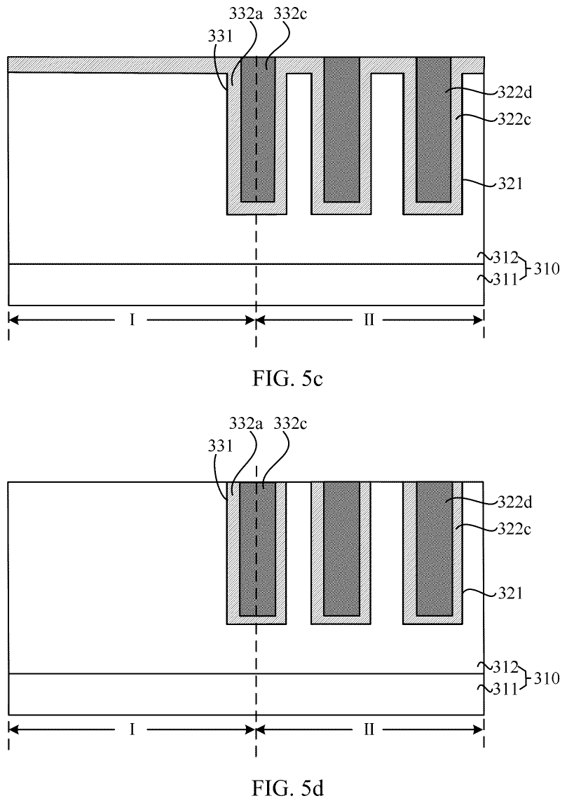

FIG. 4 shows a flowchart of a method 400 for fabricating a semiconductor device in accordance with an embodiment of the present disclosure. The semiconductor device could be one of the semiconductor devices in FIGS. 2 and 3. The method 400 combines the trench technology and BCD process technology, for fabricating the semiconductor device that combines low specific on-resistance with the various advantages of devices manufactured using BCD process technology.

As shown in FIG. 4, the method 400 includes steps S110-S130.

In step S110, providing a semiconductor layer, the semiconductor layer is partitioned into a first region and a second region.

In step S120, forming multiple first device structures in the first region by BCD process technology.

In step S130, forming multiple second device structures in the second region. Each second device structure includes a trench power device with a T-shaped gate electrode.

The steps outlined above identify the device structures required for device fabrication without implying a specific sequence of formation.

In some embodiments, the first device structure may include multiple devices manufactured using BCD process technology, like bipolar device, COMS device, DMOS device, etc.

In some embodiments, the method 400 further includes: forming an isolation structure positioned in between the first region and the second region.

In some embodiments, the method 400 further includes: forming multiple isolation structures, wherein each one of the multiple first structures is positioned between two neighboring devices of the first device structures in the first region.

In some embodiments, forming the isolation structure includes: forming a first trench; filling the first trench with a dielectric layer and an electrode. Compared with the conventional isolation structure between the devices using BCD process technology, the isolation structures with trenches in the embodiments of the present disclosure have reduced area, resulting in a higher integration density.

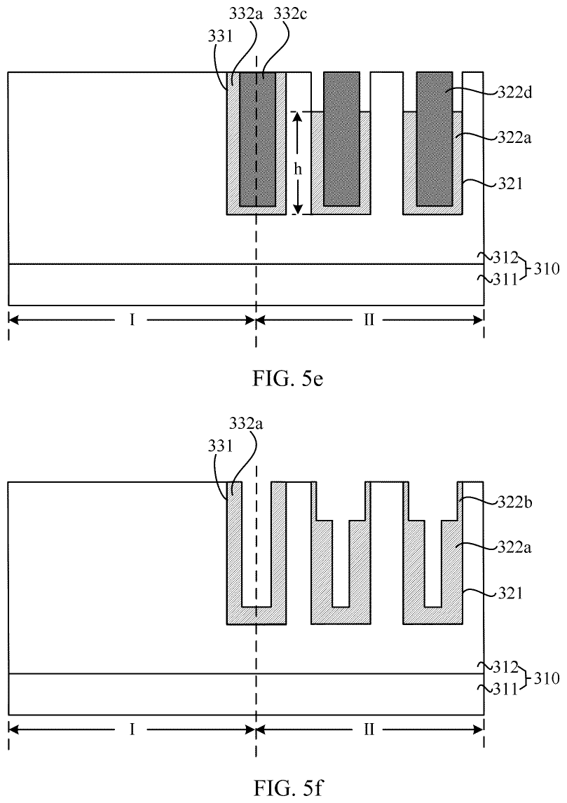

FIGS. 5a to 5f schematically show the cross sectional views of the semiconductor device during conducting the steps of the method 400, in accordance with an embodiment of the present disclosure. This method 400 will be described in detail below with reference to FIGS. 5a to 5f.

As shown in FIG. 5a, the semiconductor layer 310 is partitioned into a first region I and a second region II which are laterally adjacent. Then a common mask is adopted to etch the first trenches 331 positioned in the first region I and between the first region I and the second region II, and the second trenches 321 positioned in the second region II. Specifically, a photoresist layer may be formed on the surface of the epitaxial layer 312. Targeted regions of the photoresist layer are exposed, forming a patterned photoresist layer. The patterned photoresist layer is then adopted as a mask to etch the epitaxial layer 312, forming the first trenches 331 and the second trenches 321 having the same depth.

It should be understood that for a positive photoresist, the exposed regions correspond to the openings formed in the photoresist layer, and thus correspond to the positions of the first trenches 331 and second trenches 321. For a negative photoresist, the unexposed regions correspond to the openings formed in the photoresist layer, and thus correspond to the positions of the first trenches 331 and second trenches 321.

In FIG. 5b, a dielectric layer is formed on the sidewalls and bottom surface of each one of the first trenches 331 and the second trenches 321 by deposition or thermal growth. The dielectric layer formed on the sidewalls and the bottom surface of the first trench 331 is referred to as the first dielectric layer 332a. The dielectric layer formed on the sidewalls and the bottom surface of the second trench 321 is referred to as a target dielectric layer 322c. The thicknesses of the first dielectric layer 332a and the target dielectric layer 322c are the same.

In some embodiments, the first dielectric layer 332a and the target dielectric layer 322c formed by a thermal growth is an oxide layer. In the embodiment that the epitaxial layer 312 is made of doped silicon material, the oxide layer may be of silicon dioxide. In some embodiments, the first dielectric layer 332a and the target dielectric layer 322c formed by deposition may also be an oxide layer.

In the embodiments of the present disclosure, the first trenches 331 and the second trenches 321 are formed simultaneously. Also, the first dielectric layer 332a and the target dielectric layer 322c are formed simultaneously. The simultaneous formation of the trenches and the simultaneous formation of the dielectric layers simplify the process flow. Furthermore, the formation of the first trenches 331 and the second trenches 321 is achieved with a sole mask, resulting in fewer mask layers, which is beneficial for reducing fabrication costs.

In a first embodiment, after forming the target dielectric layer 322c, the second region II may be shielded by a mask, and the deposition or thermal growth process then be continued until the first trenches 331 are fully filled, forming the isolation structure with a dielectric material filler adopted as the insulating structure. In a second embodiment, as shown in FIG. 5c, after forming the first dielectric layer 332a and the target dielectric layer 322c, insulating material, like silicon nitride or photoresist, is filled into the first trenches 331 and the second trenches 321. The insulating material filled in the first trench 331 form a first sacrificial structure 332c, and as such the first dielectric layer 332a together with the first sacrificial structure 332c constitute the insulating structure. The insulating material filled in the second trench 321 forms a second sacrificial structure 322d. In a third embodiment, the structures in the first trenches 331 and the second trenches 321 are formed by the steps shown in FIGS. 5c to 5f, which will be detailed below. Among the above mentioned embodiments, the second and third embodiments are beneficial for reducing mask layers, thereby lowering device fabrication costs.

It should be noted that filling the entire first trench 331 with the first sacrificial structure 332c, and filling the entire second trench 321 with the second sacrificial structure 322d, facilitates controlling the height of the sacrificial structures across the entire wafer and the subsequent etch depth control of the target dielectric layer 322c, which improves the consistency of the shape and size of the T-shaped gate electrode and enhances the production quality and yield of the semiconductor device.

During the process of forming the dielectric layer described above, the surface of the epitaxial layer 312 will also be covered by the dielectric layer, as shown in FIG. 5b. Therefore, after forming the first sacrificial structure 332c and the second sacrificial structure 322d, the dielectric layer distributed on the surface of the epitaxial layer 312 may be removed, and the material filling the first trenches 331 and the second trenches 321 could be flush with the surface of the epitaxial layer 312, as shown in FIG. 5d. This process may be achieved by methods such as chemical mechanical polishing (CMP).

During when the target dielectric layer 322c is etched, the first region I and the first trench in between the first region I and the second region II are mask-protected. The etching process removes a portion of the target dielectric layer 322c in the upper section of the second trench 321, to form the second dielectric layer 322a, as shown in FIG. 5e. After etching away the portion of the target dielectric layer 322c, a third dielectric layer 322b is formed on the sidewalls where the target dielectric layer 322c is etched away, as shown in FIG. 5f. The thickness of the third dielectric layer 322b is less than that of the second dielectric layer 322a. As such, the second trench 321, after forming the third dielectric layer 322b and removing the second sacrificial structure 322d, has a T-shaped void as shown in FIG. 5f. Filling this T-shaped void with conductive material forms the T-shaped gate electrode 323. Said conductive material is, for example, polysilicon.

In some embodiments, when the epitaxial layer 312, the target dielectric layer 322c and the second sacrificial structure 322d are made of different materials, a first selective etching process may be adopted to remove the portion of the target dielectric layer 322c at the upper section of the second trench 321, which saves a mask and lower the fabrication costs associated with using a mask for etching.

The first selective etching process adopts a first etchant. Compared to the materials of the epitaxial layer 312 and the second sacrificial structure 322d, the first etchant has a higher etching rate for the material of the target dielectric layer 322c, which allows the portion of the target dielectric layer 322c at the upper section of the second trench 321 to be removed while the epitaxial layer 312 and the second sacrificial structure 322d are not damaged. The fact that the second sacrificial structure 322d is not damaged facilitates etching the target dielectric layer 322c into the shape shown in FIG. 5e, i.e., etching the target dielectric layer 322c and the portion at the upper section of the second trench 321 is removed. The remaining part of the target dielectric layer 322c (i.e., the part in FIG. 5e where the distance from the bottom surface of the second trench 321 is not greater than the height h) will not be etched by the first etchant left after the second sacrificial structure 322d were removed if the second sacrificial structure 322d keeps not damaged during when etching the target dielectric layer 322c. It could be seen that the second sacrificial structure 322d serves a critical function in the process of removing the portion of the target dielectric layer 322c at the upper section of the second trench 321.

After removing the portion of the target dielectric layer 322c at the upper section of the second trench 321, the second sacrificial structure 322d is removed. As shown in the embodiment of FIG. 5f, the second sacrificial structure 322d could be removed simultaneously with the removal of the first sacrificial structure 332c. Subsequently, a conductive material is adopted to simultaneously fill the first trench 331 where the first sacrificial structure 332c was removed and fill the second trench 321 where the third dielectric layer 322b was formed and the second sacrificial structure 322d was removed. This forms the electrode 332b shown in FIG. 3 within the first trench 331, and the T-shaped gate electrode 323 shown in FIG. 3 within the second trench 321. The above presented process eliminates the need for a mask to cover the surface of the first region I while removing the second sacrificial structure 322d and forming the T-shaped gate electrode 323. It should be understood that although the electrode 332b is formed of conductive material, the first dielectric layer 332a encapsulating the electrode 332b maintains the insulating integrity of the isolation structure 332.

In some embodiments, when the epitaxial layer 312, the second dielectric layer 322a, the first sacrificial structure 332c and second sacrificial structure 322d are made of different materials, a second selective etching process may be adopted to remove the first sacrificial structure 332c and the second sacrificial structure 322d, which saves numerous mask layers and high fabrication costs associated with using a mask for etching.

The second selective etching process adopts a second etchant different from the first etchant. Compared to the materials of the epitaxial layer 312 and the second dielectric layer 322a, the second etchant has a higher etch rate for the material of the first sacrificial structure 332c and the second sacrificial structure 322d, which allows the first sacrificial structure 332c and the second sacrificial structure 322d to be removed while the epitaxial layer 312 and the second dielectric layer 322a are not damaged. As such, the fabricated T-shaped gate has a high yield.

It should be understood that after filling the T-shaped void shown in FIG. 5f with conductive material, step S130 of forming the second device structure in the second region II further includes processes such as forming the source and drain, insulating layer, conductive pillars, and conductive layer, which are not detailed here.

In step S120, forming the first device structure in the first region I is implemented by BCD process technology. The process may include forming bipolar devices, CMOS devices and DMOS devices. As an example, to form a DMOS device, the drift region 341, the body region 342, the source region 343, the body contact region 344, the drain region 345, and the gate electrode 346 are formed as shown in FIG. 3. The process of manufacturing bipolar devices, CMOS devices, and DMOS devices using BCD process technology are known by persons of ordinary skill in the art and is not detailed here.

The embodiments of the present application may be used not only for devices using silicon as the semiconductor base layer, but also for devices using wide-bandgap materials, such as SiC and GaN, as the semiconductor base layer.

While various embodiments have been described above to illustrate the semiconductor device and its manufacturing method of the present disclosure, it should be understood that they have been presented by way of example only, and not limitation. Rather, the scope of the present disclosure is defined by the following claims and includes combinations and sub-combinations of the various features described above, as body as variations and modifications thereof, which would occur to persons skilled in the art upon reading the foregoing description.

1. A semiconductor device, comprising:
a semiconductor layer comprising a first region and a second region;
a plurality of first device structures formed in the first region, wherein one of the plurality of first device structures comprises one of the bipolar device, the CMOS (complementary metal-oxide-semiconductor transistor) device and the DMOS (double diffusion metal-oxide-semiconductor transistor) device; and
a plurality of second device structures formed in the second region, wherein at least one of the plurality of second device structures comprises a trench power device with a T-shaped gate electrode.

2. The semiconductor device of claim 1, further comprising:
an isolation structure positioned in between the first region and the second region, wherein the isolation structure comprises a first trench and an insulating structure in the first trench.

3. The semiconductor device of claim 2, wherein the insulating structure comprises dielectric material filling the first trench.

4. The semiconductor device of claim 2, wherein the insulating structure comprises:
a first dielectric layer covering sidewalls and a bottom surface of the first trench; and
an electrode in the first trench, wherein the electrode is isolated from the first trench by the first dielectric layer.

5. The semiconductor device of claim 4, wherein each one of the plurality of second device structures comprises:
a second trench;
a second dielectric layer covering a bottom surface and sidewalls of a lower section of the second trench;
a third dielectric layer covering sidewalls of an upper section of the second trench; and
a T-shaped gate electrode in the second trench, wherein the T-shaped gate electrode is insulated from the second trench by the second dielectric layer and the third dielectric layer.

6. The semiconductor device of claim 5, wherein the first trench and the second trench have the same depth.

7. The semiconductor device of claim 5, wherein the first dielectric layer and the second dielectric layer have the same thickness.

8. The semiconductor device of claim 5, wherein the electrode and the T-shaped gate electrode are made of the same conductive material.

9. The semiconductor device of claim 1, further comprising:
a plurality of isolation structures positioned in the first region of the semiconductor layer, wherein each one of the plurality isolation structures comprises a first trench and an insulating structure in the first trench, and
wherein each one of the plurality of isolation structures is positioned between two neighboring first device structures.

10. The semiconductor device of claim 1, wherein each one of the plurality of second device structures comprises:
a second trench;
a dielectric layer covering sidewalls and a bottom surface of the second trench; and
a T-shaped gate electrode in the second trench, wherein the T-shaped gate electrode is insulated from the second trench by the dielectric layer.

11. The semiconductor device of claim 1, further comprising:
an insulating layer covered partial of a surface of the second region of the semiconductor layer;
a conductive layer overlying the insulating layer; and
multiple conductive pillars extend vertically through the insulating layer to connect the conductive layer to selective regions of the surface of the epitaxial layer between neighboring second device structures.

12. A method of fabricating a semiconductor device, comprising:
providing a semiconductor layer, wherein the semiconductor layer comprises a first region and a second region;
forming a plurality of first device structures in the first region of the semiconductor layer by BCD process technology; and
forming a plurality of second device structures in the second region of the semiconductor layer, wherein at least one of the plurality of second device structures includes a trench power device with a T-shaped gate electrode.

13. The method of fabricating a semiconductor device of claim 12, further comprising:
forming an isolation structure in between the first region and the second region of the semiconductor layer.

14. The method of fabricating a semiconductor device of claim 13, wherein the isolation structure comprises:
a first trench; and
an insulating structure in the first trench, wherein the insulating structure comprises dielectric material.

15. The method of fabricating a semiconductor device of claim 13, wherein the isolation structure comprises:
a first trench;
an insulating structure in the first trench, wherein the insulating structure comprises a first dielectric layer; and
an electrode in the first trench, wherein the electrode is insulated from the first trench by the first dielectric layer.

16. The method of fabricating a semiconductor device of claim 15, wherein forming a plurality of second device structures in the second region of the semiconductor layer comprises:
forming a plurality of second trenches in the second region of the semiconductor layer, wherein the plurality of second trenches are formed simultaneously with the first trenches by a mask;
forming a dielectric layer covering sidewalls and a bottom surface of each one of the plurality of second trenches, wherein the dielectric layer is formed simultaneously with the first dielectric layer; and
etching away the dielectric layer at the sidewalls of an upper section of each one of the plurality of second trenches, wherein the dielectric layer covering the sidewalls and the bottom surface of a lower section of each one of the plurality of second trenches after etching forms a second dielectric layer;
forming a third dielectric layer at the sidewall of the upper section of each one of the plurality of second trenches, wherein the third dielectric layer is thinner than the second dielectric layer; and
filling a T-shaped void formed by the second dielectric layer and the third dielectric layer in each one of the plurality of second trenches with a conductive material to form a T-shaped gate electrode.

17. The method of fabricating a semiconductor device of claim 15, wherein forming a plurality of second device structures in the second region of the semiconductor layer comprises:
forming a plurality of second trenches in the second region of the semiconductor layer, wherein the plurality of second trenches are formed simultaneously with the first trenches by a mask;
forming a dielectric layer covering sidewalls and a bottom surface of each one of the plurality of second trenches, wherein the dielectric layer is formed simultaneously with the first dielectric layer; and
filling each one of the first trenches to form a first scarification structure in each one of the first trenches;
filling each one of the plurality of second trenches to form a second scarification structure in each one of the plurality of second trenches, wherein the first scarification structure and the second scarification structure are formed simultaneously in a step;
etching away the dielectric layer at the sidewalls of an upper section of each one of the plurality of second trenches, wherein the dielectric layer at the sidewalls and the bottom surface of a lower section of each one of the plurality of second trenches after etching forms a second dielectric layer;
removing the first scarification structures and the second scarification structures;
forming a third dielectric layer at the sidewalls of the upper section of each one of the plurality of second trenches, wherein the third dielectric layer is thinner than the second dielectric layer;
filling a T-shaped void formed by the second dielectric layer and the third dielectric layer in each one of the plurality of second trenches with conductive material to form a T-shaped gate electrode; and
filling a void formed by the first dielectric layer in each one of the first trenches with the conductive material to form an electrode, wherein the electrode and the T-shaped gate electrode are formed simultaneously.
